(19) United States
(12) Patent Application Publication
(10) Pub. No.: US 2013/0257423 A1
(43) Pub. Date: Oct. 3, 2013

(54) HYBRID MAGNETIC SENSOR

(71) Applicants: Kang-Shuo Chang, Yilan County (TW); Meng-Huang Lai, Taipei city (TW)

(72) Inventors: Kang-Shuo Chang, Yilan County (TW); Meng-Huang Lai, Taipei city (TW)

(73) Assignee: Isentek Inc., New Taipei City (TW)

(21) Appl. No.: 13/438,223

(22) Filed: Apr. 3, 2012

(51) Int. Cl. G01R 33/06

(52) U.S. Cl. 324/251

(57) ABSTRACT

A magnetic sensor is disclosed. The magnetic sensor includes a first magnetic sensing device, a second magnetic sensing device and a third magnetic sensing device. The first magnetic sensing device and the second magnetic sensing device sense X-axis and Y-axis magnetic fields. The third magnetic sensing device is a Hall device to sense Z-axis magnetic field by Hall effect. The first magnetic sensing device is disposed in a 90 degrees position related to the second magnetic sensing device.

### BACKGROUND

1. Field of Invention

The present invention relates to a sensor, and more particularly to a Hybrid Magnetic sensor.

2. Description of Related Art

Magnetic sensor can sense the earth magnetic field to search the direction and position. Therefore, magnetic sensor is a main element in a navigation system, such as a global positioning system or an electronic compass.

Modern electronic products are designed to include multiple functions. A navigation system can help users to guide direction and find position. Therefore, the navigation system is usually integrated into an electronic product to serve the users. For reducing the electronic products size, a small size navigation system is needed. Because the magnetic sensor is a main element in a navigation system, reducing the size of the magnetic sensor is a method to get small size navigation system.

### SUMMARY

An object of the present invention is to provide a small size magnetic sensor.

The present invention provides a magnetic sensor that includes a first sensing device and a Hall sensing device. The first sensing device senses X-axis magnetic field and Y-axis magnetic field, and the Hall sensing device senses Z-axis magnetic field.

In an embodiment, the first sensing device is a magnetoresistance sensor, a magnetoinductive sensor or a fluxgate magnetic sensor.

In an embodiment, the first sensing device further comprises a first magnetic sensing device and a second magnetic sensing device, wherein the first magnetic sensing device senses X-axis magnetic field, the second magnetic sensing device senses Y-axis magnetic field and the first magnetic sensing device and the second magnetic sensing device are arranged in perpendicular to each other.

In an embodiment, the magnetic sensor further includes a substrate, and the first magnetic sensing device, the second magnetic sensing device and the Hall sensing device are disposed on the substrate. The Hall sensing device is disposed on the substrate and does not protrude out a surface of the substrate. A detecting circuit is formed in the substrate, the first magnetic sensing device and the second magnetic sensing device are connected to the detecting circuit using wire bonding technology.

In an embodiment, the magnetic sensor further includes a substrate, and the first magnetic sensing device and the second magnetic sensing device are disposed neighbor to two sides of the substrate respectively, and the Hall sensing device is disposed on the substrate. The Hall sensing device is disposed on the substrate and does not protrude out a surface of the substrate. A detecting circuit is formed in the substrate, the first magnetic sensing device and the second magnetic sensing device are connected to the detecting circuit using wire bonding technology.

In an embodiment, a chip package technology or a silicon wafer integration technology is used to form the magnetic sensor.

The present invention provides a magnetic sensor that includes a substrate, a first magnetic sensing device, a second magnetic sensing device and a third magnetic sensing device. A detecting circuit is formed in the substrate. The third magnetic sensing device is disposed on the substrate and does not protrude out a surface of the substrate. The first magnetic sensing device, the second magnetic sensing device and the third magnetic sensing device are connected to the detecting circuit respectively. The first magnetic sensing device and the second magnetic sensing device sense X-axis and Y-axis magnetic fields. The third magnetic sensing device is a Hall device to sense Z-axis magnetic field by Hall effect. The first magnetic sensing device is disposed in a 90 degrees position related to the second magnetic sensing device.

In an embodiment, the first magnetic sensing device, the second magnetic sensing device and the third magnetic sensing device are disposed on the substrate.

In an embodiment, the first magnetic sensing device and the second magnetic sensing device are disposed neighbor to the two sides of the substrate respectively. The third magnetic sensing device is disposed on the substrate.

In an embodiment, the first magnetic sensing device and the second magnetic sensing device are connected to the detecting circuit using wire bonding technology.

In an embodiment, the first magnetic sensing device and the second magnetic sensing device sense X-axis and Y-axis magnetic fields by Magnetoresistance Effect.

Accordingly, in such magnetic sensor structure, a first sensing unit to sense X-axis and Y-axis magnetic fields and a Hall sensing unit to sense Z-axis magnetic field. Therefore, it is not necessary to arrange the first sensing unit and the Hall sensing unit t perpendicular to the substrate. The hall sensing device further can bury into the substrate. Therefore, the magnetic sensor is thinned.

### BRIEF DESCRIPTION OF THE DRAWINGS

In order to make the foregoing as well as other aspects, features, advantages, and embodiments of the present invention more apparent, the accompanying drawings are described as follows:

FIG. 1 illustrates a magnetic sensing device using Magnetoresistance Effect technology to sense magnetic field.

FIG. 2 illustrates a magnetic sensing device using Hall Effect technology to sense magnetic field.

FIG. 3 illustrates a schematic diagram of a magnetic sensor according to an embodiment of the present invention.

FIG. 4 illustrates a schematic diagram of a magnetic sensor according to another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Magnetoresistance Effect is the property of a material to change the value of its electrical resistance when an external magnetic field is applied to it. Such material is usually used in a magnetic sensing device to sense magnetic field, such as a giant magnetoresistance (GMR) magnetic sensing device, an anisotropic magnetoresistance (AMR) magnetic sensing device and so on. Anisotropic magnetoresistance (AMR) refers to resistance changes in ferromagnetic metals in which the resistance is dependent upon the relationship between the axis of current flow and the orientation of the magnetization. Giant magnetoresistance (GMR) is a quantum mechanical magnetoresistance effect observed in thin-film structures composed of alternating ferromagnetic and non-magnetic layers. In multilayer GMR, two or more magnetic layers are separated by a very thin (about 1 nm) non-magnetic (insulating) layer.

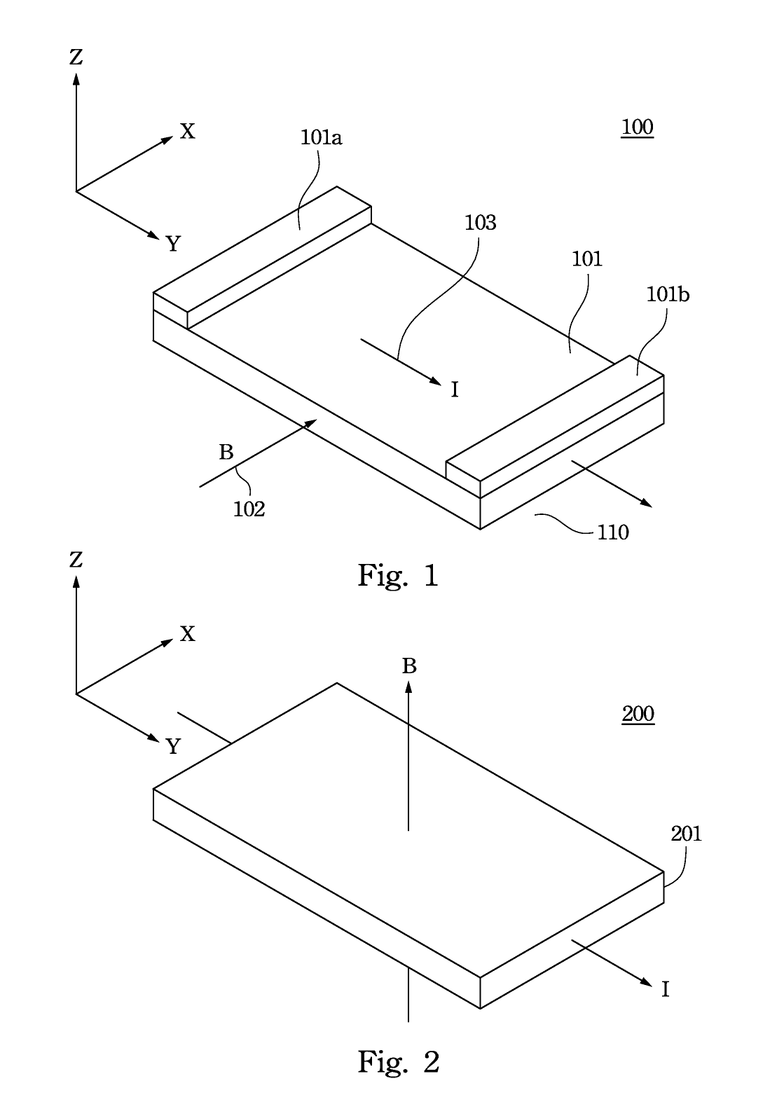

FIG. 1 illustrates a magnetic sensing device using Magnetoresistance Effect technology to sense magnetic field. The magnetic sensing device 100 includes a sensing unit 101. The value of the magnetic field can be measured by detecting the change of electrical resistance value of the sensing unit 101. For example, when a magnetic field 102 with a direction perpendicular to the flowing direction of current 103 is applied to the sensing unit 101 that is formed by Fe—Ni alloy, the electrical resistance value between the two ends 101a and 101b of the sensing unit 101 is changed. Therefore, the value of the magnetic field 102 can be got by measuring the change value of the electrical resistance between the two ends 101a and 101b of the sensing unit 101. Accordingly, the sensing unit 101 is used to sense a magnetic filed with a direction perpendicular to the flowing direction of current 103 in the sensing unit 101. In other words, when the sensing unit 101 is arranged in the Y direction, that is, the current in the sensing unit 101 flows along the Y direction, a magnetic field along X direction can be sensed by the sensing unit 101. In contrast, when the sensing unit 101 is arranged in the X direction, that is, the current in the sensing unit 101 flows along the X direction, a magnetic field along Y direction can be sensed by the sensing unit 101. That is, two sensing units 101 that are arranged in perpendicular to each other are needed to sense magnetic fields in two dimensions (X direction and Y direction). Therefore, the magnetic sensing device 100 using Magnetoresistance Effect technology is used to sense a magnetic field located in a plane with the magnetic sensing device 100. Accordingly, when the magnetic sensing device 100 is used to sense a magnetic field along Z direction, the magnetic sensing device 100 has to be arranged in the Z direction, which is unfavorable in thinning the package. Moreover, an additional adjusting process is required when the magnetic sensing device 100 arranged in Z direction is not exactly perpendicular to the surface of a substrate.

FIG. 2 illustrates a magnetic sensing device using Hall Effect technology to sense magnetic field. The Hall effect is the production of a voltage difference (the Hall voltage) across an electrical conductor, transverse to an electric current in the conductor and a magnetic field perpendicular to the current. A hall sensing device 200 uses Hall Effect technology to sense a magnetic field. The semiconductor material, such as Ge, Si, GaAs, InAs, or Ti, is used to fabricate a hall sensing device 200. The hall sensing device includes a plate 201. A current I flows through the plate 201. The current I is a conductor. Current I consists of the movement of many small charge carriers. When a magnetic field B is present that is perpendicular to the flowing direction of current I, the magnetic field B moves charge carriers to accumulate on one face of the plate 201, which leaves equal and opposite charges exposed on the other face of the plate 201. The separation of charge establishes an electric field that is related to the magnetic field B and the control current I. In other words, the value of the magnetic field B can be measured according to the control current I and the generated electric field. Therefore, the hall sensing device 200 is used to sense a magnetic field B perpendicular to the hall sensing device 200. That is, when a it is not necessary to arrange the hall sensing device 200 perpendicular to a substrate for sensing a Z-direction magnetic field.

According to the present invention, the magnetic sensor includes a first sensing unit and a second sensing unit. The first sensing unit uses a first-type sensing technology to sense X-axis and Y-axis magnetic fields respectively. The second sensing unit uses a second-type sensing technology to sense Z-axis magnetic field. In an embodiment, the first-type sensing technology is a Magnetoresistance Effect technology and the second-type sensing technology is a Hall effect technology. However, in another embodiment, the first-type sensing technology is a magnetoinductive sensing technology or a fluxgate magnetic sensing technology. That is, the first sensing unit is a magnetoresistance sensor, a magnetoinductive sensor or a fluxgate magnetic sensor. The second sensing unit is a Hall sensor. That is, a first sensing unit with Magnetoresistance Effect technology is used to sense X-axis and Y-axis magnetic fields respectively and a second sensing unit with Hall effect technology is used to sense Z-axis magnetic field. Therefore, no any sensing unit arranged perpendicular to the substrate is needed. The magnetic sensor is thinned. The size of the magnetic sensor can be reduced. Two embodiments are described in the following paragraphs to explain the claimed invention. However, the application of the claimed invention is not limited by the two embodiments.

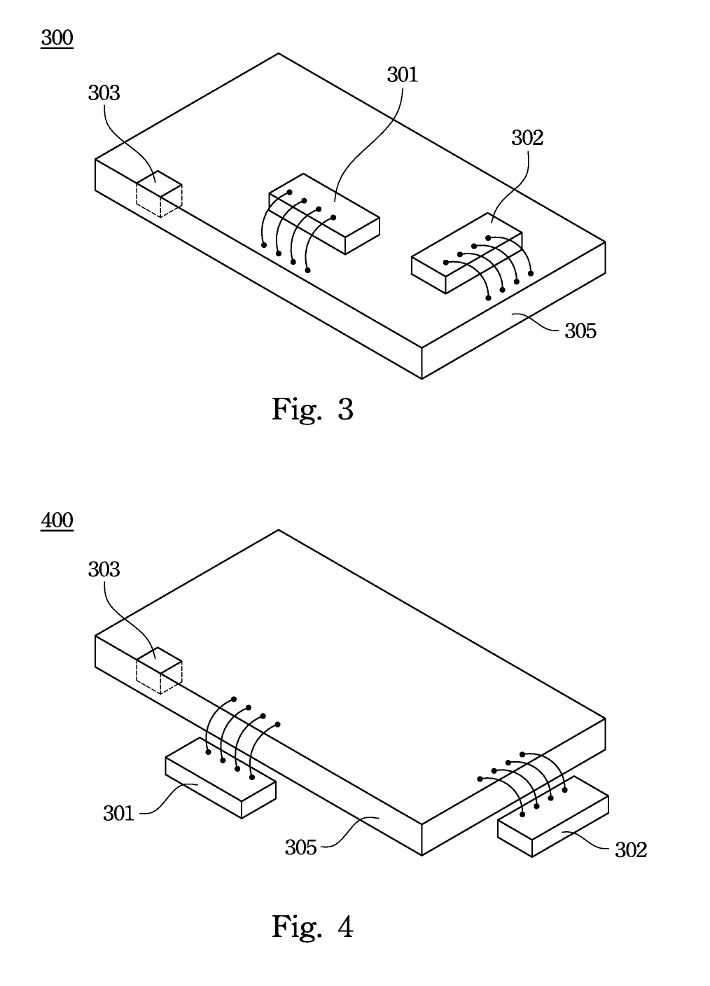

FIG. 3 illustrates a schematic diagram of a magnetic sensor according to an embodiment of the present invention. The magnetic sensor 300 includes a first sensing unit to sense X-axis and Y-axis magnetic fields and a second sensing unit to sense Z-axis magnetic field. The first sensing unit further comprises a first magnetic sensing device 301 and a second sensing device 302 both having a first-type sensing technology. The second unit is a third magnetic sensing device 303 having a second-type sensing technology. In an embodiment, the first-type sensing technology is a Magnetoresistance Effect technology. However, in another embodiment, the first-type sensing technology is a magnetoinductive sensing technology or a fluxgate magnetic sensing technology. The second-type sensing technology is a Hall effect technology. Accordingly, in this embodiment, both the first magnetic sensing device 301 and the second sensing device 302 use Magnetoresistance Effect technology to sense X-axis and Y-axis magnetic fields respectively. The third magnetic sensing device 303 uses Hall effect technology to sense Z-axis magnetic field. The first magnetic sensing device 301 and the second magnetic sensing device 302 are arranged in perpendicular to each other and disposed on the substrate 305.

Moreover, a detecting circuit (not shown in FIG. 3) is formed on the substrate 305. The first magnetic sensing device 301 and the second magnetic sensing device 302 are connected to the detecting circuit using wire bonding technology. In an embodiment, input pads and output pads of the first magnetic sensing device 301 and the second magnetic sensing device 302 respectively are connected to corresponding input pads and output pads of the detecting circuit on the substrate 305. In an embodiment, the third magnetic sensing device 303 is a hall device that can be formed with the detecting circuit. That is, the third magnetic sensing device 303 and the detecting circuit are formed using a same process. In an embodiment, the third magnetic sensing device 303 is formed in the substrate 305 and does not protrude out a surface of the substrate 305, which can help to simplify the package process. On the other hand, the input pads and output pads are formed on the bottom surface of the third magnetic sensing device 303. When the third magnetic sensing device 303 is formed in the substrate 305, the input pads and output pads formed on the bottom surface are connected to corresponding input pads and output pads of the detecting circuit.

FIG. 4 illustrates a schematic diagram of a magnetic sensor according to another embodiment of the present invention. The magnetic sensor 400 includes a first sensing unit to sense X-axis and Y-axis magnetic fields and a second sensing unit to sense Z-axis magnetic field. The first sensing unit further comprises a first magnetic sensing device 301 and a second sensing device 302 both having a first-type sensing technology. The second unit is a third magnetic sensing device 303 having a second-type sensing technology. In an embodiment, the first-type sensing technology is a Magnetoresistance Effect technology. However, in another embodiment, the first-type sensing technology is a magnetoinductive sensing technology or a fluxgate magnetic sensing technology. The second-type sensing technology is a Hall effect technology. Accordingly, in this embodiment, both the first magnetic sensing device 301 and the second sensing device 302 use Magnetoresistance Effect technology to sense X-axis and Y-axis magnetic fields respectively. The third magnetic sensing device uses Hall effect technology to sense Z-axis magnetic field. The first magnetic sensing device 301 and the second magnetic sensing device 302 are arranged in perpendicular to each other and disposed neighbor to two sides of the substrate 305. Moreover, a detecting circuit (not shown in FIG. 4) is formed on the substrate 305. The first magnetic sensing device 301 and the second magnetic sensing device 302 are connected to the detecting circuit using wire bonding technology. In an embodiment, the third magnetic sensing device 303 is a hall device. The third magnetic sensing device 303 and the detecting circuit are formed using a same process. In an embodiment, the third magnetic sensing device 303 is formed in the substrate 305 and does not protrude out a surface of the substrate 305, which can help to simplify the package process. On the other hand, a chip package technology or a silicon wafer integration technology can be used to form the magnetic sensor with a first magnetic sensing device 301, a second magnetic sensing device 302 and a third magnetic sensing device 303.

Accordingly, the magnetic sensor includes a first sensing unit to sense X-axis and Y-axis magnetic fields and a Hall sensing unit to sense Z-axis magnetic field. No any sensing unit is arranged in perpendicular to the substrate. The hall sensing unit further can bury into the substrate. Therefore, the magnetic sensor is thinned. The size of the magnetic sensor is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A hybrid magnetic sensor, comprising:
a first sensing device; and
a Hall sensing device;
wherein the first sensing device senses X-axis magnetic field and/or Y-axis magnetic field, and the Hall sensing device senses Z-axis magnetic field.

2. The hybrid magnetic sensor of claim 1, wherein the first sensing device is a magnetoresistance sensor, a magnetoinductive sensor, a fluxgate magnetic sensor or a combination of the above sensor.

3. The hybrid magnetic sensor of claim 1, wherein the first sensing device further comprises a first magnetic sensing device and a second magnetic sensing device, wherein the first magnetic sensing device senses X-axis magnetic field, the second magnetic sensing device senses Y-axis magnetic field and the first magnetic sensing device and the second magnetic sensing device are arranged in perpendicular to each other.

4. The hybrid magnetic sensor of claim 3, wherein the magnetic sensor further includes a substrate, and the first magnetic sensing device, the second magnetic sensing device and the Hall sensing device are disposed on the substrate.

5. The hybrid magnetic sensor of claim 4, wherein the Hall sensing device is disposed on the substrate and does not protrude out a surface of the substrate.

6. The hybrid magnetic sensor of claim 4, wherein a detecting circuit is formed in the substrate, the first magnetic sensing device and the second magnetic sensing device are connected to the detecting circuit using wire bonding technology.

7. The hybrid magnetic sensor of claim 3, wherein the magnetic sensor further includes a substrate, and the first magnetic sensing device and the second magnetic sensing device are disposed neighbor to two sides of the substrate respectively, and the Hall sensing device is disposed on the substrate.

8. The hybrid magnetic sensor of claim 7, wherein the Hall sensing device is disposed on the substrate and does not protrude out a surface of the substrate.

9. The hybrid magnetic sensor of claim 7, wherein a detecting circuit is formed in the substrate, the first magnetic sensing device and the second magnetic sensing device are connected to the detecting circuit using wire bonding technology.

10. The hybrid magnetic sensor of claim 1, wherein a chip package technology or a silicon wafer integration technology is used to form the magnetic sensor.

11. A hybrid magnetic sensor, comprising:
a substrate with a detecting circuit;
a first magnetic sensing device;
a second magnetic sensing device; and
a third magnetic sensing device, wherein the third magnetic sensing device is disposed in the substrate and does not protrude out a surface of the substrate,
wherein the first magnetic sensing device, the second magnetic sensing device and the third magnetic sensing device are connected to the detecting circuit respectively, and the first magnetic sensing device senses X-axis magnetic field, the second magnetic sensing device senses Y-axis magnetic field, and the third magnetic sensing device is a Hall device and senses Z-axis magnetic field, the first magnetic sensing device and the second magnetic sensing device are arranged in perpendicular to each other.

12. The hybrid magnetic sensor of claim 11, wherein the first magnetic sensing device, the second magnetic sensing device and the third magnetic sensing device are disposed on the substrate.

13. The hybrid magnetic sensor of claim 11, wherein the first magnetic sensing device and the second magnetic sensing device are disposed neighbor to two sides of the substrate respectively, and the third magnetic sensing device is disposed on the substrate.

14. The hybrid magnetic sensor of claim 11, wherein the first magnetic sensing device and the second magnetic sensing device are connected to the detecting circuit using wire bonding technology.

15. The hybrid magnetic sensor of claim 11, wherein the first magnetic sensing device uses Magnetoresistance Effect technology to sense X-axis magnetic field and the second magnetic sensing device uses Magnetoresistance Effect technology to sense Y-axis magnetic field.
